(19) United States
(12) Patent Application Publication
(10) Pub. No.: US 2004/0166628 A1
(43) Pub. Date: Aug. 26, 2004

(54) Methods and apparatus for forming dielectric structures in integrated circuits

(76) Inventors: In-Sung Park, Seoul (KR); Ki-Vin Im, Gyeonggi-do (KR); Ki-Yeon Park, Gyeonggi-do (KR); Jae-Hyun Yeo, Seoul (KR); Yun-Jung Lee, Seoul (KR)

Correspondence Address: Robert M. Meeks, Myers Bigel Sibley & Sajovee, Post Office Box 37428, Raleigh, NC, 27627, US

(21) Appl. No.: 10/769,929

(22) Filed: Feb. 2, 2004

(30) Foreign Application Priority Data
Feb. 3, 2003 (KR) 2003-6513

(51) Int. Cl. H01L 21/8242

(52) U.S. Cl. 438/243

(57) ABSTRACT

In some embodiments, a multi-layer dielectric structure, such as a capacitor dielectric region, is formed by forming a first dielectric layer on a substrate according to a CVD process and forming a second dielectric layer directly on the first dielectric layer according to an ALD process. In further embodiments, a multi-layer dielectric structure is formed by forming a first dielectric layer on a substrate according to an ALD process and forming a second dielectric layer directly on the first dielectric layer according to a CVD process. The CVD-formed layers may comprise one selected from the group consisting of SiO₂, Si₃N₃, Ta₂O₅, HfO₂, ZrO₂, TiO₂, Y₂O₃, Pr₂O₃, La₂O₃, Nb₂O₅, SrTiO₃ (STO), BaSrTiO₃ (BST) and PbZrTiO₃ (PZT). The ALD-formed layers may comprise one selected from the group consisting of SiO₂, Si₃N₃, Al₂O₃, Ta₂O₅, HfO₂, ZrO₂, TiO₂, Y₂O₃, Pr₂O₃, La₂O₃, Nb₂O₅, SrTiO₃ (STO), BaSrTiO₃ (BST) and PbZrTiO₃ (PZT).

### CROSS REFERENCE TO RELATED APPLICATIONS

This application claims priority under 35 U.S.C. § 119 to Korean Patent Application 2003-6513 filed on Feb. 3, 2003, the contents of which are herein incorporated by reference in their entirety.

### BACKGROUND OF THE INVENTION

The present invention relates to methods and apparatus for forming dielectric structures, and more particularly, to apparatus and methods for forming multi-layer dielectric structures in integrated circuits.

Integrated circuits, such as dynamic random access memory (DRAM) devices, typically include a unit cell that has one transistor and one capacitor. The capacitor is usually composed of a lower electrode, a dielectric layer and an upper electrode. The capacitor should have sufficient capacitance so as to properly operate the DRAM. Factors affecting the capacitance of the capacitor include an effective area of the capacitor, a dielectric constant of the dielectric layer, and a thickness of the dielectric layer.

The distance between unit cells has generally been decreased due to the size reductions associated with increased integration of the DRAM device. This can gradually reduce the effective area of the capacitors in such cells. When the dielectric layer having a high dielectric constant and a thinner thickness is employed for the capacitor, it typically is important to control the thickness of the dielectric layer to ensure the adequate capacitance of the capacitor. Particularly, it is generally desirable to uniformly deposit the dielectric layer on the entire surface of the lower electrode.

Techniques for forming such a capacitor dielectric layer include a sputtering method, a molecular beam epitaxy (MBE) method, a chemical vapor deposition (CVD) method, and an atomic layer deposition (ALD) method. Among these methods for forming the dielectric layer, the CVD and ALD processes can be advantageously used to form a uniform thin dielectric layer.

In a CVD process, a first reactant, such as a metal organic reactant, and a second reactant, such as an oxide, are simultaneously introduced in a reaction chamber so that a dielectric layer is formed due to a surface reaction between the first and the second reactants. In an ALD process, a first reactant and a second reactant are provided in a reaction chamber so that a dielectric layer is formed by the surface reaction between the first and the second reactants. CVD processes generally have the advantages that the formation speed of the dielectric layer is relatively fast and the extension capability of selecting the metal organic reactant is comparatively wide because of the use of a vaporizer. However, there may be some disadvantages, such as inferior step coverage of the dielectric film and relatively high formation temperature. For a typical ALD process, formation speed of the dielectric layer may be relatively slow and the selection of the metal organic reactants may be comparatively narrow. However, ALD processes generally have the advantages that the thickness of the dielectric layer can be precisely controlled because of the deposition of atoms and that a dielectric layer having a wide area can be formed at a relatively low temperature.

Examples of materials deposited for forming the dielectric layer of the capacitor using the above-mentioned two methods generally include SiO₂, Ta₂O₅, HfO₂, ZrO₂, TiO₂, Y₂O₃, Pr₂O₃, La₂O₃, Nb₂O₅, SrTiO₃ (STO), BaSrTiO₃ (BST), and PbZrTiO₃ (PZT). Recent research shows that the electric characteristics of a capacitor including at least two stacked layers composed of the above-mentioned materials or tiny metal-implanted layers as the dielectric layer may perform better than a capacitor that has any one layer composed of the above-mentioned materials as the dielectric layer. Examples of typical stacked layers include SiO₂/Si₃N₄/SiO₂, Ta₂O₅/HfO₂, Ta₂O₅/TiO₂, Al₂O₃/TiO₂, and Al₂O₃/HfO₂. The metal-implanted dielectric layer may include Ta₂O₅ doped with Ti, HfO₂ doped with Al, or ZrO₂ doped with Al.0

FIG. 1 shows a conventional apparatus for forming stacked dielectric layers disclosed in Korean Laid Open Patent Publication No.2002-52644. Referring to FIG. 1, the conventional apparatus comprises a transfer chamber 10, a loading chamber 20, an unloading chamber 30, a first chamber 40 and a second chamber 50. The loading chamber 20, the unloading chamber 30, and the first and second chambers 40 and 50 are disposed around the transfer chamber 10. Silicon nitride (SiN) is deposited by an ALD process in the first chamber 40, while silicon oxide (SiO₂) is deposited by an ALD process in the second chamber 50. A dielectric layer is formed by an ALD process in the first chamber 40 and the second chamber 50 in the conventional apparatus. Thus, although the thickness of the dielectric layer can be controlled and the dielectric layer can be formed at a relatively low temperature in a wide area, the formation speed of the dielectric layer may be slow and the selection of metal organic reactants may be comparatively narrow in comparison with CVD processes. As a result, the fabrication yield of the semiconductor manufacturing process may be reduced. Further, in the conventional apparatus, the SiN typically can be deposited only in the first chamber 40, and SiO₂ can be deposited only in the second chamber 50. Accordingly, the conventional apparatus typically cannot be adapted for forming other kinds of dielectric layers, such as Ta₂O₅, HfO₂, and TiO₂, which recently are being used as dielectric layers for capacitors.

### SUMMARY OF THE INVENTION

According to some embodiments of the present invention, a multi-layer dielectric structure, such as a capacitor dielectric region, is formed by forming a first dielectric layer on a substrate according to a CVD process and forming a second dielectric layer directly on the first dielectric layer according to an ALD process. The first dielectric layer may comprise one selected from the group consisting of SiO₂, Si₃N₃, Ta₂O₅, HfO₂, ZrO₂, TiO₂, Y₂O₃, Pr₂O₃, La₂O₃, Nb₂O₅, SrTiO₃ (STO), BaSrTiO₃ (BST) and PbZrTiO₃ (PZT), and the second dielectric layer may comprise one selected from the group consisting of SiO₂, Si₃N₃, Al₂O₃, Ta₂O₅, HfO₂, ZrO₂, TiO₂, Y₂O₃, Pr₂O₃, La₂O₃, Nb₂O₅, SrTiO₃ (STO), BaSrTiO₃ (BST) and PbZrTiO₃ (PZT).

According to further embodiments of the present invention, a multi-layer dielectric structure is formed by forming a first dielectric layer on a substrate according to an ALD process and forming a second dielectric layer directly on the first dielectric layer according to a CVD process. The first dielectric layer may comprise one selected from the group consisting of SiO₂, Si₃N₃, Ta₂O₅, HfO₂, ZrO₂, TiO₂, Y₂O₃, Pr₂O₃, La₂O₃, Nb₂O₅, SrTiO₃ (STO), BaSrTiO₃ (BST) and PbZrTiO₃ (PZT), and the second dielectric layer may comprise one selected from the group consisting of SiO₂, Si₃N₃, Al₂O₃, Ta₂O₅, HfO₂, ZrO₂, TiO₂, Y₂O₃, Pr₂O₃, La₂O₃, Nb₂O₅, SrTiO₃ (STO), BaSrTiO₃ (BST) and PbZrTiO₃ (PZT).

In additional method embodiments of the present invention, an integrated circuit capacitor is formed by forming a first electrode on a substrate, forming a first dielectric layer on the first electrode using a first one of an ALD process and a CVD process, forming a second dielectric layer on the first dielectric layer using a second one of the ALD process and the CVD process, and forming a second electrode on the second dielectric layer. Forming a first dielectric layer may comprise forming the first dielectric layer in a first chamber, while forming a second dielectric layer may comprise depositing the second dielectric layer in a second chamber. The substrate may be transferred between chambers after forming the first dielectric layer while maintaining a vacuum on the substrate, e.g., via a transfer chamber configured to be selectively coupled to the first and second chambers.

In some embodiments, the first dielectric layer comprises one selected from the group consisting of SiO₂, Si₃N₃, Ta₂O₅, HfO₂, ZrO₂, TiO₂, Y₂O₃, Pr₂O₃, La₂O₃, Nb₂O₅, SrTiO₃ (STO), BaSrTiO₃ (BST) and PbZrTiO₃ (PZT), and the second dielectric layer comprises one selected from the group consisting of SiO₂, Si₃N₃, Al₂O₃, Ta₂O₅, HfO₂, ZrO₂, TiO₂, Y₂O₃, Pr₂O₃, La₂O₃, Nb₂O₅, SrTiO₃ (STO), BaSrTiO₃ (BST) and PbZrTiO₃ (PZT). In other embodiments, the second dielectric layer comprises one selected from the group consisting of SiO₂, Si₃N₃, Ta₂O₅, HfO₂, ZrO₂, TiO₂, Y₂O₃, Pr₂O₃, La₂O₃, Nb₂O₅, SrTiO₃ (STO), BaSrTiO₃ (BST) and PbZrTiO₃ (PZT), and the first dielectric layer comprises one selected from the group consisting of SiO₂, Si₃N₃, Al₂O₃, Ta₂O₅, HfO₂, ZrO₂, TiO₂, Y₂O₃, Pr₂O₃, La₂O₃, Nb₂O₅, SrTiO₃ (STO), BaSrTiO₃ (BST) and PbZrTiO₃ (PZT).

According to further aspects of the present invention, an apparatus for forming multi-layer dielectric structures on a semiconductor substrate includes a first chamber configured to form dielectric layers according to a chemical vapor deposition (CVD) process, a second chamber configured to form dielectric layers according to an atomic layer deposition (ALD) process, and means for providing a substrate to one of the first and second chambers for formation of a first dielectric layer on the substrate and for automatically transferring the substrate to a second one of the first and second chambers for formation of a second dielectric layer directly on the first dielectric layer. The means for providing the substrate to a first one of the first and second chambers for formation of a first dielectric layer on the substrate and for automatically transferring the substrate to the second one of the first and second chambers for formation of a second dielectric layer on the first dielectric layer may include means for transferring the substrate between the first and second chambers while maintaining a vacuum on the substrate, e.g., a transfer chamber configured to be selectively coupled to the first and second chambers. The apparatus may further include a loadlock chamber configured to vacuumize the transfer chamber and a cooling chamber configured to maintain a temperature of the transfer chamber.

In further embodiments, the first chamber includes one of a plurality of first chambers configured to form dielectric layers according to respective CVD processes and the second chamber includes one of a plurality of second chambers configured to form dielectric layers according to respective ALD processes. The means for providing a substrate to a first one of the first and second chambers for formation of a first dielectric layer on the substrate and for transferring the substrate to a second one of the first and second chambers for formation of a second dielectric layer on the first dielectric layer includes means for providing a substrate to any of the first chambers for formation of a first dielectric layer on the substrate and for transferring the substrate to any of the second chambers for formation of a second dielectric layer on the first dielectric layer. In other embodiments, the means for providing a substrate to a first one of the first and second chambers for formation of a first dielectric layer on the substrate and for transferring the substrate to a second one of the first and second chambers for formation of a second dielectric layer on the first dielectric layer includes means for providing a substrate to any of the second chambers for formation of a first dielectric layer on the substrate and for transferring the substrate to any of the first chambers for formation of a second dielectric layer on the first dielectric layer.

### BRIEF DESCRIPTION OF THE DRAWINGS

FIG. 1 is a plan view illustrating a conventional apparatus for forming dielectric layers.

FIG. 2 is a plan view illustrating apparatus for forming dielectric layers according to some embodiments of the present invention.

FIG. 3 is a plan view illustrating apparatus for forming dielectric layers according to further embodiments of the present invention.

FIG. 4 is a graph illustrating electrical characteristics of a capacitor fabricated using apparatus according to some embodiments of the present invention in comparison with those of a capacitor fabricated using a conventional technique.

FIG. 5 is a graph illustrating electrical characteristics of a capacitor fabricated according to some embodiments of the present invention after heat treatment in comparison with those of a capacitor fabricated using a conventional technique after heat treatment.

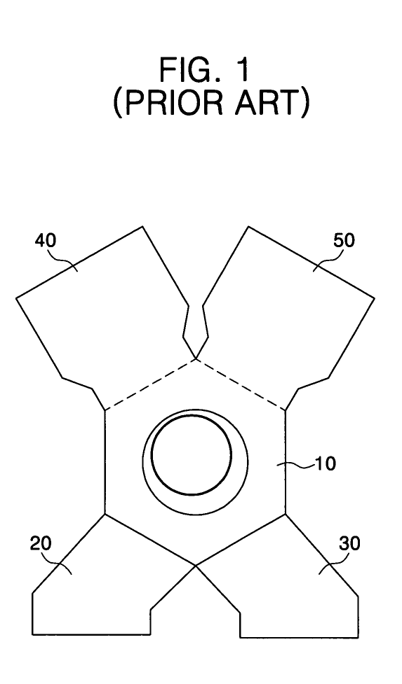

### DESCRIPTION OF THE PREFERRED EMBODIMENTS

The present invention will be described more fully hereinafter with reference to the accompanying drawings, in which embodiments of the invention are shown. This invention, however, may be embodied in many different forms and should not be construed as limited to the embodiments set forth herein. Rather, these embodiments are provided so that this disclosure will be thorough and complete, and will fully convey the scope of the invention to those skilled in the art. In the drawings, the thickness of layers and regions are exaggerated for clarity. It will also be understood that when a layer is referred to as being “on” another layer or substrate, it can be directly on the other layer or substrate, or intervening layers may also be present.

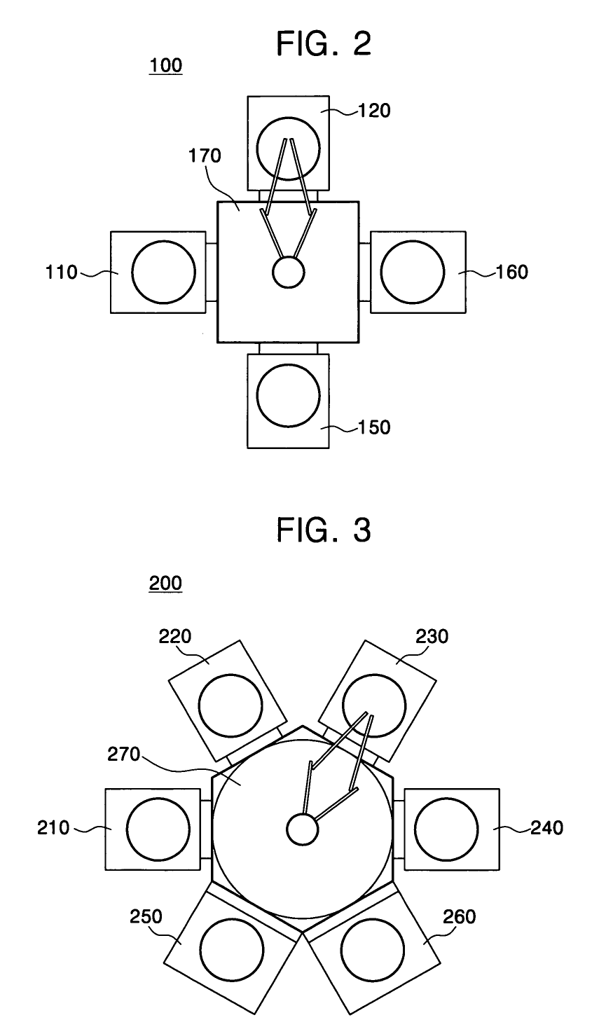

Referring to FIG. 2, an apparatus 100 for forming dielectric layers according to some embodiments of the present invention includes a transfer chamber 170 having a rectangular cross-section. A loadlock chamber 150, first and second chambers 110 and 120, and a cooling chamber 160 are disposed on respective first, second, third and fourth sides of the transfer chamber 170. The loadlock chamber 150 vacuumizes the transfer chamber 170 so that dielectric layers can be formed in-situ without the interruption of vacuum of the first chamber 110 and the second chamber 120. The cooling chamber 160 controls the temperature of the transfer chamber 170.

According to some embodiments, a first dielectric layer is formed on a wafer (or other substrate) by a CVD process in the first chamber 110. In the second chamber 120, a second dielectric layer is formed on the first dielectric layer by an ALD process. The first chamber 110 and the second chamber 120 are controlled to have a temperature in a range from about room temperature (that is, about 25° C.) to about 700° C. and a pressure in a range from about 1×10⁻⁶ Torr to about atmospheric pressure.

The first dielectric layer can be formed quickly because of the use of the CVD process. The second dielectric layer can be readily formed while controlling a thickness thereof, and the second dielectric layer can be widely and uniformly formed at a relatively low temperature because the second dielectric layer is formed on the first dielectric layer using the ALD process. Examples of materials that can be used to form the first dielectric layer include SiO₂, Si₃N₃, Ta₂O₅, HfO₂, ZrO₂, TiO₂, Y₂O₃, Pr₂O₃, La₂O₃, Nb₂O₅, SrTiO₃ (STO), BaSrTiO₃ (BST), and PbZrTiO₃ (PZT). Examples of materials that can be used to form the second dielectric layer include SiO₂, Si₃N₃, Al₂O₃, Ta₂O₅, HfO₂, ZrO₂, TiO₂, Y₂O₃, Pr₂O₃, La₂O₃, Nb₂O₅, SrTiO₃ (STO), BaSrTiO₃ (BST), and PbZrTiO₃ (PZT). The materials used to form the second dielectric layer may be substantially identical to the materials used to form the first dielectric layer, with the addition of Al₂O₃. Namely, though the materials that can be used to form the first dielectric layer can be fully deposited by the CVD process or the ALD process, the second dielectric layer also can be advantageously formed using Al₂O₃. When Al₂O₃ is deposited by a CVD process in accordance with a conventional method, although the deposition speed of the Al₂O₃ is faster than that of the ALD process, the conventional method generally requires an additional process, such as a curing process, due to numerous impurities and instability caused by the CVD process. However, when Al₂O₃ is deposited by an ALD process in accordance with embodiments of the present invention, although the deposition speed of the Al₂O₃ is relatively slower than with a typical CVD process, the present invention does not require an additional process, such as a curing process, due to relatively small impurities and stability thereof. Particularly, according to some embodiments of the present invention, an extended deposition time for an ALD process can be compensated for by using a CVD process in conjunction with the ALD process, such that total deposition time can be kept relatively short.

In addition, a conventional CVD process for depositing Al₂O₃ on a wafer typically is performed at a relatively low pressure. CVD generally affects the crystalline quality of the wafer, surface morphology, uniformity and dielectric constant of the dielectric layer in accordance with temperature. For example, although an Al₂O₃ layer formed at a high temperature of approximately 1,000° C. by a CVD process may have an excellent crystalline quality, the Al₂O₃ layer generally has inferior characteristics in terms of surface morphology, uniformity and dielectric constant thereof. However, when Al₂O₃ is deposited by the ALD process according to embodiments of the present invention, surface morphology, uniformity and dielectric constant of the Al₂O₃ layer can be improved. The crystalline quality can be improved by annealing the Al₂O₃ layer.

In the above-described embodiments, the first chamber 110 is used as a CVD deposition chamber and the second chamber 120 is used as an ALD deposition chamber. However, reverse combinations can be used according to further embodiments. Namely, the first chamber 110 may be used as an ALD deposition chamber and the second chamber 120 may be used as a CVD deposition chamber. If Al₂O₃ is used, it should be deposited in the first chamber 110.

Referring to FIG. 3, an apparatus 200 for forming dielectric layers according to further embodiments of the present invention includes a transfer chamber 270 having a hexagonal cross-section. Two loadlock/cooling chambers 250 and 260, and first, second, third and fourth chambers 210, 220, 230 and 240 are disposed on respective first, second, third, fourth, fifth and sixth sides of the transfer chamber 270 In the first chamber 210, Al₂O₃ layers may be formed by an ALD process. Ta₂O₅ layers may be formed in the second chamber 220 by a CVD process. In the third chamber 230, HfO₂ layers may be formed by a CVD process. TiO₂ layers may be formed in the fourth chamber 240 by an ALD process.

The apparatus 200 has first and fourth chambers 210 and 240 in which ALD processes are performed, and CVD processes are performed in the second and third chambers 220 and 230. Hereinafter, materials of the dielectric layers formed in the first to fourth chambers 210, 220, 230 and 240 will be described. However, it should be noted that materials adopted in the first to fourth chambers 210, 220, 230 and 240 may vary. Al₂O₃ preferably is deposited by an ALD process, as described above.

When dielectric layers are formed, not all of the four chambers 210, 220, 230 and 240 are needed for forming the dielectric layers, as the dielectric layers generally include only two films. Accordingly, one of the first and fourth chambers 210 and 240 having ALD types and one of the second and third chambers 220 and 230 having CVD types may be selected for a formation of layers on a particular wafer. The operation order of the selected two chambers may be varied. In additional embodiments, the transfer chamber 270 may have an octagonal shape so that the deposition chambers may comprise three chambers for ALD processes and three chambers for CVD processes.

### EXAMPLES

Table 1 shows differences between a conventional technique for forming dielectric layers and a technique for forming such layers according to some embodiments of the present invention.

TABLE 1

| | | | Technique according to | |
|---|---|---|---|---|
| | | | exemplary embodiments | |
| | Conventional technique | | of the invention | |
| | Chamber | | | |
| | first chamber | second | first chamber | second |
| | of an ALD | chamber | of a | chamber of an |
| | type | of an ALD type | CVD type | ALD type |
| Dielectric | Ta₂O₅ | TiO₂ | Ta₂O₅ | TiO₂ |
| layer | | | | |

As shown in Table 1, the first and second chambers of the conventional apparatus were both ALD type chambers. In contrast, in the technique according to some embodiments of the present invention, the first chamber is a CVD type chamber and the second chamber is an ALD type chamber. Dielectric layers of Ta₂O₅/TiO₂ were formed using the conventional technique and the technique embodiments of the present invention, respectively.

A cylindrical structured capacitor was formed on a wafer according to a conventional technique. A polysilicon layer was formed (for a lower electrode) and then rinsed. Subsequently, in order to increase the electrical conductivity of the polysilicon layer, phosphorus (P) was doped into the polysilicon layer at a temperature of approximately 750° C. for about 60 seconds. A rapid thermal nitridation (RTN) process was then executed on the doped poly silicon layer at a temperature of approximately 750° C. for about 180 seconds. The RTN process was performed to activate the polysilicon layer, to repress the formation of a native oxide film, and to form an oxidation-preventing layer after a successive heat treatment process.

A Ta₂O₅ layer having a thickness of about 20 Å was then formed on the polysilicon layer using an ALD process with a formation rate of about 4 Å/min at a temperature of approximately 350° C. Ta(C₂H₅O)₅ was used as a metal source, and O₃ was used as an oxidant. Ta(C₂H₅O)₅ and O₃ were then purged by an argon (Ar) gas. Four processes including a Ta (C₂H₅O)₅ supplying process, a first purging process, an O₃ supplying process and a second purging process were then repeatedly carried out until a Ta₂O₅ layer having a desired thickness was obtained. An annealing process using UV- O₃ was then executed at a temperature of approximately 700° C. for about 120 seconds, thereby curing the Ta₂O₅ layer.

Subsequently, a TiO₂ layer having a thickness of about 100 Å was formed on the Ta₂O₅ layer by an ALD process at a temperature of approximately 350° C. Ti(C₃H₇O)₄ was used as a metal source, and O₃ was used as an oxidant. Ti(C₃H₇O)₄ and O₃ were then purged using an Ar gas. Four processes including a Ti(C₃H₇O)₄ supplying process, a first purge process, an O₃ supplying process and a second purge process were repeatedly executed until a TiO₂ layer having a desired thickness was obtained. An annealing process using O₂ was then executed at a temperature of approximately 600° C. for about 30 minutes, thereby curing weak portions of the Ta₂O₅/TiO₂ layer.

Finally, an Ru layer having a thickness of about 300 Å was formed on the Ta₂O₅/TiO₂ layer by a CVD process to form an upper electrode. An additional Ru layer having a thickness of about 300 Å was continuously formed by a physical vapor deposition (PVD) method.

A cylindrical structured capacitor was also formed on a wafer according to exemplary embodiments of the present invention. A polysilicon lower electrode layer was formed and then rinsed. In order to increase the electrical conductivity of the polysilicon layer, phosphorus was doped into the polysilicon layer at a temperature of approximately 750° C. for about 60 seconds. An RTN process was then executed on the doped poly silicon layer at a temperature of approximately 750° C. for about 180 seconds.

A Ta₂O₅ layer having a thickness of about 20 Å was then formed on the polysilicon layer using a CVD process with a formation rate of about 43 Å/min at a temperature of approximately 460° C. Ta(C₂H₅O)₅ was used as a metal source and O₃ was used as an oxidant. An annealing process using UV-O₃ was performed on the Ta₂O₅ layer about 120 seconds at a temperature of approximately 700° C., thereby curing the Ta₂O₅ layer.

Subsequently, a TiO₂ layer having a thickness of about 100 Å was formed on the Ta₂O₅ layer using an ALD process at a temperature of approximately 350° C. Ti(C₃H₇O)₄ was used as a metal source and O₃ was used as an oxidant. Ti(C₃H₇O)₄ and O₃ were purged using an Ar gas. Four processes including a Ti(C₃H₇O)₄ supplying process, a first purging process, an O₃ supplying process and a second purging process were repeatedly executed until a TiO₂ layer having a desired thickness was obtained. An annealing process using O₂ was then executed at a temperature of approximately 600° C. for about 30 minutes, thereby curing weak portions of the Ta₂O₅/TiO₂ layer.

Finally, an Ru layer having a thickness of about 300 Å thickness was formed on the Ta₂O₅/TiO₂ layer by a CVD process as an upper electrode. An additional Ru layer having a thickness of about 300 Å was then continuously formed by a PVD method

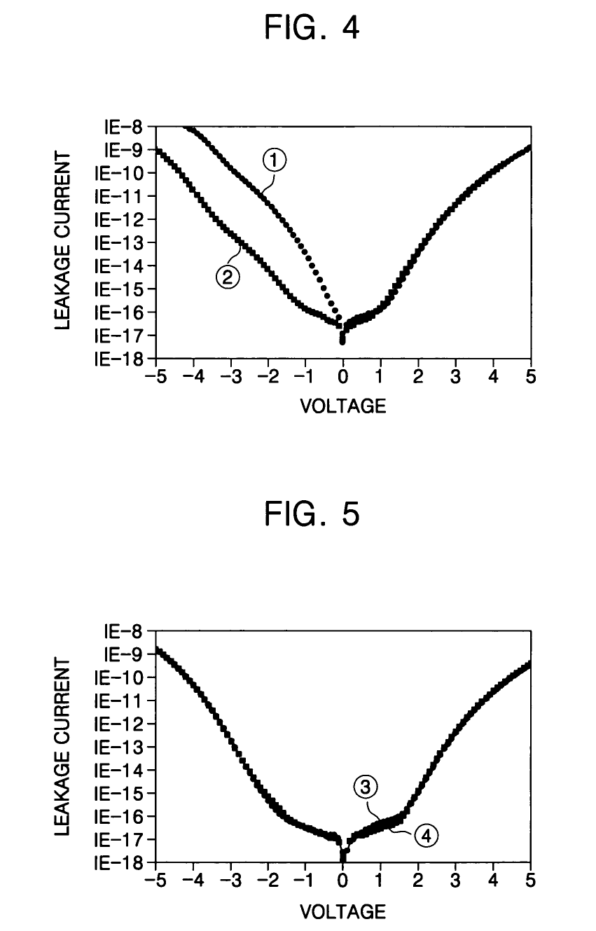

The electrical characteristics of capacitors formed using the conventional technique and capacitors formed according to embodiments of the present invention were measured. FIG. 4 is a graph showing the electrical characteristics of a capacitor fabricated according to embodiments of the present invention relative to the electrical characteristics of a capacitor fabricated using a conventional technique. In FIG. 4, the horizontal axis represents voltage and the vertical axis represents leakage current. The capacitors have substantially identical capacitance of about 20.2 fF/cell. In FIG. 4, the curve 1 indicates the leakage current of a capacitor formed according to a conventional technique and the curve 2 indicates the leakage current of a capacitor formed according to embodiments of the present invention.

As shown in FIG. 4, when the voltage is positive, the difference of the electrical characteristics between the two capacitors is relatively small. However, when the voltage is negative, the leakage current indicated by the curve 1 is significantly higher than that indicated by the curve 2. Namely, the leakage current of the conventional capacitor was found to be much higher than that of the capacitor formed according to embodiments of the present invention. Therefore, the electric characteristics of a capacitor formed according to embodiments of the present invention might be more desirable than those of a conventional capacitor. The deposition time for forming the dielectric layers according to embodiments of the present invention was about 10 times faster than that of the conventional technique. That is, a dielectric layer formed according to embodiments of the present invention might be formed about 10 times faster than a conventional dielectric layer. Furthermore, dielectric layers formed according to embodiments of the present invention might have excellent electrical characteristics in comparison with conventional dielectric layers.

After the two types of capacitors were stabilized, the leakage currents from the two types of capacitors were again measured. After a heat treatment process was executed under an oxygen atmosphere at a temperature of approximately 400° C., the measured leakage currents are illustrated in FIG. 5. In FIG. 5, a curve 3 indicates the leakage current of the capacitor formed according to the conventional technique and the curve 4 indicates the leakage current of the capacitor formed according to embodiments of the present invention.

As shown in FIG. 5, whether the voltage was positive or negative, the difference of the electrical characteristics between the two capacitors was relatively small. However, as described above, because deposition speed for a dielectric layer formed according to embodiments of the present invention might be about 10 times faster than that of the conventional dielectric layer, a dielectric layer according to embodiments of the present invention might be formed much more quickly than a dielectric layer formed using conventional techniques.

According to some embodiments of the present invention, a multi-layer dielectric structure, such as a capacitor dielectric, includes two dielectric layers formed by respective CVD and ALD processes. Thus, apparatus and methods according to embodiments of the present invention can enjoy advantages of both the CVD process and the ALD process, that is, relatively quick formation and relatively high stability. Furthermore, electrical characteristics of a capacitor with a dielectric formed according to embodiments of the present invention can be superior to that of a capacitor with a conventionally formed dielectric.

In the drawings and specification, there have been disclosed typical embodiments of the invention and, although specific terms are employed, they are used in a generic and descriptive sense only and not for purposes of limitation, the scope of the invention being set forth in the following claims.

What is claimed is:

1. A method of forming a multi-layer dielectric structure, the method comprising:
forming a first dielectric layer on a substrate according to a CVD process; and
forming a second dielectric layer directly on the first dielectric layer according to an ALD process.

2. The method according to claim 1, wherein the first dielectric layer comprises one selected from the group consisting of SiO₂, Si₃N₃, Ta₂O₅, HfO₂, ZrO₂, TiO₂, Y₂O₃, Pr₂O₃, La₂O₃, Nb₂O₅, SrTiO₃ (STO), BaSrTiO₃ (BST) and PbZrTiO₃ (PZT).

3. The method according to claim 1, wherein the second dielectric layer comprises one selected from the group consisting of SiO₂, Si₃N₃, Al₂O₃, Ta₂O₅, HfO₂, ZrO₂, TiO₂, Y₂O₃, Pr₂O₃, La₂O₃, Nb₂O₅, SrTiO₃ (STO), BaSrTiO₃ (BST) and PbZrTiO₃ (PZT).

4. The method according to claim 1, wherein the first dielectric layer includes HfO₂ and the second dielectric layer includes Al₂O₃.

5. The method according to claim 1, wherein forming a first dielectric layer comprises forming the first dielectric layer at a temperature in a range from about 25° C. to about 700° C. and a pressure in a range from about 1×10⁻⁶ Torr to about 760 Torr during the CVD process, and wherein forming a second dielectric layer comprises forming the second dielectric layer at a temperature in a range from about 25° C. to about 700° C. and a pressure in a range from about 1×10⁻⁶ Torr to about 760 Torr during the ALD process.

6. A method of forming a multi-layer dielectric structure, the method comprising:
forming a first dielectric layer on a substrate according to an ALD process; and
forming a second dielectric layer directly on the first dielectric layer according to a CVD process.

7. The method according to claim 6, wherein the first dielectric layer comprises one selected from the group consisting of SiO₂, Si₃N₃, Ta₂O₅, HfO₂, ZrO₂, TiO₂, Y₂O₃, Pr₂O₃, La₂O₃, Nb₂O₅, SrTiO₃ (STO), BaSrTiO₃ (BST) and PbZrTiO₃ (PZT).

8. The method according to claim 6, wherein the second dielectric layer comprises one selected from the group consisting of SiO₂, Si₃N₃, Al₂O₃, Ta₂O₅, HfO₂, ZrO₂, TiO₂, Y₂O₃, Pr₂O₃, La₂O₃, Nb₂O₅, SrTiO₃ (STO), BaSrTiO₃ (BST) and PbZrTiO₃ (PZT).

9. The method according to claim 6, wherein the first dielectric layer includes HfO₂ and the second dielectric layer includes Al₂O₃.

10. A method of forming an integrated circuit capacitor, the method comprising:
forming a first electrode on a substrate;
forming a first dielectric layer on the first electrode using a first one of an ALD process and a CVD process;
forming a second dielectric layer on the first dielectric layer using a second one of the ALD process and the CVD process; and
forming a second electrode on the second dielectric layer.

11. The method according to claim 10, wherein forming a first dielectric layer comprises forming the first dielectric layer in a first chamber, and wherein forming a second dielectric layer comprises forming the second dielectric layer in a second chamber.

12. The method according to claim 11, further comprising transferring the substrate after forming the first dielectric layer while maintaining a vacuum on the substrate.

13. The method according to claim 12, wherein transferring the substrate after forming the first dielectric layer while maintaining a vacuum on the substrate comprises transferring the substrate via a transfer chamber configured to be selectively coupled to the first and second chambers.

14. The method according to claim 10:
wherein the first dielectric layer comprises one selected from the group consisting of SiO₂, Si₃N₃, Ta₂O₅, HfO₂, ZrO₂, TiO₂, Y₂O₃, Pr₂O₃, La₂O₃, Nb₂O₅, SrTiO₃ (STO), BaSrTiO₃ (BST) and PbZrTiO₃ (PZT); and
wherein the second dielectric layer comprises one selected from the group consisting of SiO₂, Si₃N₃, Al₂O₃, Ta₂O₅, HfO₂, ZrO₂, TiO₂, Y₂O₃, Pr₂O₃, La₂O₃, Nb₂O₅, SrTiO₃ (STO), BaSrTiO₃ (BST) and PbZrTiO₃ (PZT).

15. The method according to claim 10:
wherein the first dielectric layer comprises one selected from the group consisting of SiO₂, Si₃N₃, Al₂O₃, Ta₂O₅, HfO₂, ZrO₂, TiO₂, Y₂O₃, Pr₂O₃, La₂O₃, Nb₂O₅, SrTiO₃ (STO), BaSrTiO₃ (BST) and PbZrTiO₃ (PZT); and
wherein the second dielectric layer comprises one selected from the group consisting of SiO₂, Si₃N₃, Ta₂O₅, HfO₂, ZrO₂, TiO₂, Y₂O₃, Pr₂O₃, La₂O₃, Nb₂O₅, SrTiO₃ (STO), BaSrTiO₃ (BST) and PbZrTiO₃ (PZT).

16. An apparatus for forming multi-layer dielectric structures on a semiconductor substrate, the apparatus comprising:
a first chamber configured to form dielectric layers according to a chemical vapor deposition (CVD) process;
a second chamber configured to form dielectric layers according to an atomic layer deposition (ALD) process; and
means for providing a substrate to one of the first and second chambers for formation of a first dielectric layer on the substrate and for automatically transferring the substrate to a second one of the first and second chambers for formation of a second dielectric layer directly on the first dielectric layer.

17. The apparatus according to claim 16, wherein the means for providing the substrate to a first one of the first and second chambers for formation of a first dielectric layer on the substrate and for automatically transferring the substrate to the second one of the first and second chambers for formation of a second dielectric layer on the first dielectric layer comprises means for transferring the substrate between the first and second chambers while maintaining a vacuum on the substrate.

18. The apparatus according to claim 17, wherein the means for transferring the substrate between the first and second chambers while maintaining a vacuum on the substrate comprises a transfer chamber configured to be selectively coupled to the first and second chambers.

19. The apparatus according to claim 18, further comprising:
a loadlock chamber configured to vacuumize the transfer chamber; and
a cooling chamber configured to maintain a temperature of the transfer chamber.

20. The apparatus according to claim 16:
wherein the first chamber is configured to form dielectric layers of a material selected from the group consisting of SiO₂, Si₃N₃, Al₂O₃, Ta₂O₅, HfO₂, ZrO₂, TiO₂, Y₂O₃, Pr₂O₃, La₂O₃, Nb₂O₅, SrTiO₃ (STO), BaSrTiO₃ (BST) and PbZrTiO₃ (PZT); and
wherein the second chamber is configured to form dielectric layers of a material selected from the group consisting of SiO₂, Si₃N₃, Al₂O₃, Ta₂O₅, HfO₂, ZrO₂, TiO₂, Y₂O₃, Pr₂O₃, La₂O₃, Nb₂O₅, SrTiO₃ (STO), BaSrTiO₃ (BST) and PbZrTiO₃ (PZT).
